(19) United States
(12) Patent Application Publication
(10) Pub. No.: US 2017/0186747 A1
(43) Pub. Date: Jun. 29, 2017

(54) STRUCTURE AND METHOD FOR SiGe FIN FORMATION IN A SEMICONDUCTOR DEVICE

(71) Applicant: International Business Machines Corporation, Armonk, NY (US)

(72) Inventors: Bruce B. Doris, Brewster, NY (US); He Hong, Schenectady, NY (US); Chiahsun Tseng, Wynantskill, NY (US); Yunpeng Yin, Niskayuna, NY (US)

(21) Appl. No.: 14/982,438

(22) Filed: Dec. 29, 2015

(51) Int. Cl. H01L 27/092; H01L 29/78; H01L 29/165; H01L 21/8238; H01L 21/02

(52) U.S. Cl. CPC H01L 27/0924; H01L 21/823821; H01L 21/823807; H01L 21/823878; H01L 21/02255; H01L 21/02244; H01L 29/165; H01L 29/7848

(57) ABSTRACT

A method includes forming a semiconductor fin on a semiconductor substrate; depositing a cladding layer on a portion of the semiconductor fin, wherein the cladding layer comprises a metalloid; annealing the semiconductor substrate to oxidize the cladding layer such that ions are condensed therefrom and are diffused into the semiconductor fin while the cladding layer is converted to an oxide layer; and removing the oxide layer to expose the semiconductor fin having a diffused fin portion comprising greater than or equal to 55% of the metalloid.

### BACKGROUND

The present disclosure relates to finFET semiconductor devices, and more specifically, to a finFET including an integrated silicon germanium fin structure.

Traditional finFET semiconductor devices include a gate that fully wraps one or more semiconductor fins formed from silicon. The wrapped gate can improve carrier depletion in the channel defined by the silicon fin. Accordingly, electrostatic control of the channel defined by the silicon fin may be improved.

Recent semiconductor fabrication methods have been developed to replace pure silicon fins with silicon germanium (SiGe) fins. Forming the fins from SiGe reduces the threshold voltage (Vt) of the semiconductor device, thereby increasing the drive current that flows through the channel. Further, SiGe provides higher carrier mobility than silicon. Accordingly, SiGe fins can have improve electron hole mobility performance with respect to Si fins. Traditional methods, however, are limited to forming fins having a low concentration of germanium. Traditional methods may also form SiGe fins by epitaxially growing a SiGe layer from a silicon seed layer, which forms a physical junction between the SiGe fin and the Si seed layer. Epitaxially growing the SiGe fin, however, can result in non-uniform fin grown and various defects that occur during the growth process.

### SUMMARY

According to an embodiment, a method includes forming a semiconductor fin on a semiconductor substrate; depositing a cladding layer on a portion of the semiconductor fin, wherein the cladding layer comprises a metalloid; annealing the semiconductor substrate to oxidize the cladding layer such that ions are condensed therefrom and are diffused into the semiconductor fin while the cladding layer is converted to an oxide layer; and removing the oxide layer to expose the semiconductor fin having a diffused fin portion comprising greater than or equal to 55% of the metalloid.

According to another embodiment, a method includes forming a semiconductor fin on a semiconductor substrate; bulk patterning the fin and forming a shallow trench isolation oxide around the fin; recessing the shallow trench isolation oxide to reveal a top portion of the semiconductor fin; depositing a cladding layer on a portion of the semiconductor fin, wherein the cladding layer comprises a metalloid; annealing the semiconductor substrate to oxidize the cladding layer such that ions are condensed therefrom and are diffused into the semiconductor fin while the cladding layer is converted to an oxide layer; and removing the oxide layer to expose the semiconductor fin having a diffused fin portion comprising greater than or equal to 55% of the metalloid.

According to an embodiment, a semiconductor device includes a semiconductor substrate, wherein the substrate comprises a bulk substrate, a semiconductor on insulator, or a combination comprising at least one of the foregoing; a first semiconductor fin on the semiconductor substrate in a pFET region of the semiconductor substrate, wherein the semiconductor fin comprises germanium in an amount of greater than or equal to 55%; a second semiconductor fin on the semiconductor substrate in an nFET region of the semiconductor substrate, wherein the semiconductor fin comprises silicon; a dielectric layer deposited around the first semiconductor fin on the semiconductor substrate in the pFET region and around the second semiconductor fin on the semiconductor substrate in nFET region.

Additional features are realized through the techniques of the present invention. Other embodiments are described in detail herein and are considered a part of the claimed invention. For a better understanding of the invention and the features, refer to the description and to the drawings.

### BRIEF DESCRIPTION OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which

FIG. 1 is a cross-sectional illustration of a semiconductor device.

FIG. 2 is a cross-sectional illustration of the semiconductor device of FIG. 1 with a metalloid layer disposed around the fins.

FIG. 3 is a cross-sectional illustration of the semiconductor device of FIG. 2, with the metalloid layer diffusing into the fins.

FIG. 4 is a cross-sectional illustration of the semiconductor device of FIG. 3 after removal of the metalloid layer.

FIG. 5 is a cross-sectional illustration of another semiconductor device.

FIG. 6 is a cross-sectional illustration of the semiconductor device of FIG. 5 with a metalloid layer disposed around the fins.

FIG. 7 is a cross-sectional illustration of the semiconductor device of FIG. 6, with the metalloid layer diffusing into the fins.

FIG. 8 is a cross-sectional illustration of the semiconductor device of FIG. 7 after removal of the metalloid layer.

FIG. 9 illustrates a semiconductor device including a first semiconductor structure and a second semiconductor structure formed on a bulk substrate according to another exemplary embodiment.

FIG. 10 illustrates the semiconductor device of FIG. 9 following deposition of an oxide layer that covers the semiconductor fins of the first and second semiconductor structures.

FIG. 11 illustrates the semiconductor device of FIG. 10 following patterning of a masking layer to cover the second semiconductor structures while exposing the oxide layer corresponding to the first semiconductor structure.

FIG. 12 illustrates the semiconductor device of FIG. 11 after removing a portion of the oxide layer to expose an upper portion of the fins corresponding to the first semiconductor structure.

FIG. 13 illustrates the semiconductor device of FIG. 12 showing a silicon germanium cladding layer epitaxially grown on the exposed surfaces of the semiconductor fins corresponding to the first semiconductor structure.

FIG. 14 illustrates the semiconductor device of FIG. 13 following a thermal oxidation process that condenses germanium ions into the semiconductor fins to form silicon germanium fins corresponding to the first semiconductor structure.

### DETAILED DESCRIPTION

In semiconductor devices, silicon germanium fins can be desired to increase the performance of a p-type field effect transistor (pFET) structure within the semiconductor device for nodes less than 30 nanometers, for example, less than 20 nanometers, for example, less than 10 nanometers. Germanium concentration in silicon germanium fins can be limited by epitaxial growth where germanium concentration and epitaxial growth selectivity should be balanced.

Disclosed herein, in a first embodiment, is a method of forming silicon germanium fins in a pFET structure before gate stack deposition or dummy gate patterning. In this embodiment, after fin formation and conformal oxide deposition onto the substrate has occurred, an n-type field effect transistor (nFET) can be blocked with a mask so that a sacrificial metalloid, e.g., silicon germanium containing greater than or equal to 55% germanium with respect to the silicon, or pure germanium, can be deposited across the pFET region and the nFET region. Deposition can occur by any deposition process, including, but not limited to, physical vapor deposition (PVD), chemical vapor deposition (CVD), plasma enhanced chemical vapor deposition (PECVD), inductively coupled plasma chemical vapor deposition (ICP CVD), or a combination comprising at least one of the foregoing.

A high temperature (e.g., greater than or equal to 1,000° C.) annealing process can be utilized to drive germanium through the oxide layer and diffuse into the silicon fins in the pFET region. After diffusion, the high concentration (e.g., greater than or equal to 55% germanium) silicon germanium or germanium can be removed via a wet cleaning process. After removal, silicon germanium fins are formed in the pFET region of the semiconductor device, while silicon fins are in place in the nFET region of the semiconductor device. For both semiconductor on insulator and bulk substrate fin field effect transistors (finFET) devices, the method and devices disclosed herein can be introduced after oxide deposition, but before dummy gate deposition. Deposition can occur by any deposition process, including, but not limited to, physical vapor deposition (PVD), chemical vapor deposition (CVD), plasma enhanced chemical vapor deposition (PECVD), inductively coupled plasma chemical vapor deposition (ICP CVD), or a combination comprising at least one of the foregoing.

A high temperature (e.g., greater than or equal to 1,000° C.) annealing process can be utilized to drive germanium through the oxide layer and diffuse into the silicon fins in the pFET region. After diffusion, the high concentration (e.g., greater than or equal to 55% germanium) silicon germanium or germanium can be removed via a wet cleaning process. After removal, silicon germanium fins are formed in the pFET region of the semiconductor device, while silicon fins are in place in the nFET region of the semiconductor device. The silicon germanium fin height in the pFET region can be tuned in this manner.

In another embodiment, silicon germanium fins can be formed in a pFET channel region only, with the pFET source and drain still as silicon fins. After the dummy gate polysilicon pull with the exposed fin channel still wrapped with conformal oxide, sacrificial silicon germanium having greater than or equal to 55% germanium with respect to silicon or pure germanium can be deposited non-selectively. A high temperature (e.g., greater than or equal to 1,000° C.) annealing process can be utilized to drive germanium through the oxide layer and diffuse into the silicon fins in the pFET region. After diffusion, the high concentration (e.g., greater than or equal to 55% germanium) silicon germanium or germanium can be removed via a wet cleaning process. Silicon germanium fins are formed only in the channel region with the source and drain (S/D) still as silicon fins.

In a second embodiment, tall metalloid (e.g., silicon germanium) fins can be formed on pFET devices. For example above a layer thickness for a given concentration of silicon germanium (SiGe), the total thickness that can be grown without defects is fixed. However, with the method disclosed herein, the total thickness that can be grown without defects is fixed. For example, after bulk fin patterning and single or dual shallow trench isolation, the local shallow trench isolation oxide can be recessed to reveal a top portion of the fins. A conformal oxide layer can be deposited around the fins and the nFET region can be masked, e.g., with a boron nitride (BN) mask. A sacrificial metalloid, e.g., silicon germanium containing greater than or equal to 55% germanium with respect to the silicon or pure germanium can be deposited non-selectively across both nFET and pFET regions.

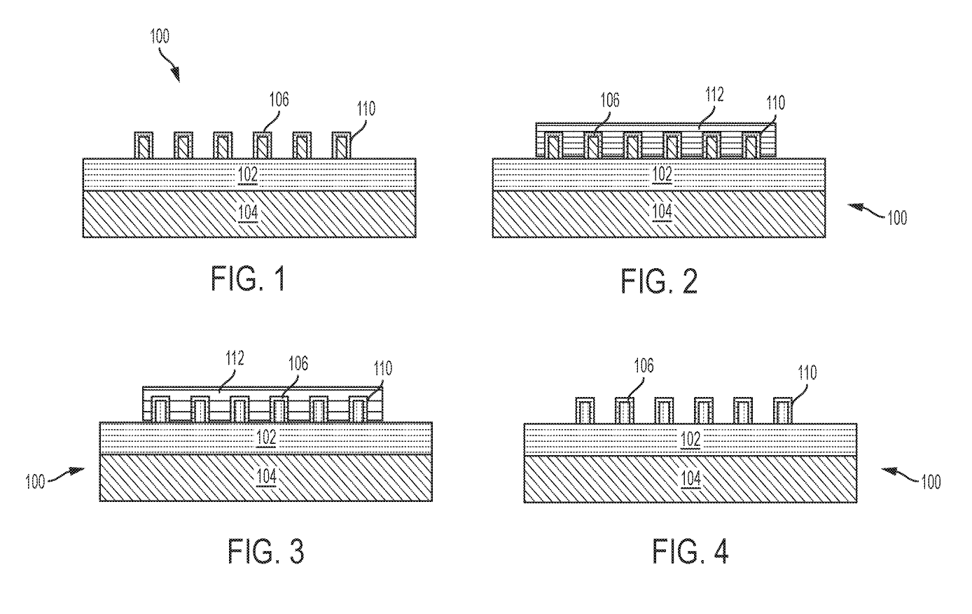

Referring to FIGS. 1 to 4, a semiconductor device 100 is indicated according to an exemplary embodiment. The semiconductor device 100 can be formed as a p-type field effect transistor (i.e., a pFET) or a n-type field effect transistor (i.e., a nFET). The semiconductor 100 device can be formed from a substrate 104. The substrate 104 can include a bulk semiconductor substrate 104 such as, for example, a bulk silicon (Si) substrate. An oxide layer 102, for example silicon dioxide (SiO₂) can be deposited over the substrate 104 as a protective layer to the substrate 104. The semiconductor device 100 can have one or more semiconductor fins 106 formed on the substrate 104. The semiconductor fins 106 may be formed by patterning the substrate 104, e.g., a bulk substrate, using, for example, a sidewall image transfer (SIT) process as understood by those ordinarily skilled in the art. A trench can be formed in the bulk substrate 104′. It is appreciated that although a bulk semiconductor substrate 104 is illustrated, the semiconductor fins 106 can be formed on a semiconductor-on-insulator (SOI) substrate as understood by those ordinarily skilled in the art.

The substrate 104 can include one or more semiconductor materials. Non-limiting examples of suitable substrate 201 materials include Si (silicon), strained Si, SiC (silicon carbide), carbon doped silicon (Si:C), Ge (germanium), SiGe (silicon germanium), SiGeC (silicon-germanium-carbon), Si alloys, Ge alloys, III-V materials (e.g., GaAs (gallium arsenide), InAs (indium arsenide), InGaAs (indium gallium arsenide) InP (indium phosphide), or aluminum arsenide (AlAs)), II-VI materials (e.g., CaSe (cadmium selenide), CaS (cadmium sulfide), CaTe (cadmium telluride), ZnO (zinc oxide), ZnSe (zinc selenide), ZnS (zinc sulfide), or ZnTe (zinc telluride)), or a combination comprising at least one of the foregoing. Other examples of substrates 104 include silicon-on-insulator (SOI) substrates and silicon-germanium on insulator substrates with buried dielectric layers

A block masking layer 110 can be deposited on the semiconductor device 100 to cover the semiconductor fins 106. A chemical vapor deposition (CVD) process can be used to deposit the block masking layer 110 along an upper surface and sidewalls of the semiconductor fins 106. The block masking layer 110 can be formed from various materials including, for example, silicon oxide (SiO₂). A chemical-mechanical planarization (CMP) process can be performed such that the block masking layer 110 is recessed and flush with the upper surface of the semiconductor fins 106 as shown in FIGS. 1 to 4.

Upper portions of the semiconductor fins 106 can be exposed after removing a portion of the block masking layer 110 using, for example, a reactive ion etching (ME) process. The ME process can be selective to silicon, for example. The amount of block masking layer 110 removed may vary based on the desired height of the semiconductor fin 106. That is, the height of the fin 106 defining the portion that will undergo thermal oxidation can be tuned (i.e., adjusted) according to the amount of block masking layer 110 that is removed. The remaining portion of the semiconductor fin 106 can therefore a non-diffused portion.

Referring now to FIG. 2, a cladding layer 112 can be epitaxially grown on the upper portion and sidewalls of the semiconductor fins 106. According to an embodiment, the cladding layer 112 can be a silicon germanium (SiGe) cladding layer 112. The cladding layer 112 can have a thickness in the lateral and/or vertical direction ranging, for example, from approximately 15 nanometers (nm) to approximately 20 nm.

In FIG. 3, the germanium from the cladding layer 112 can thermally diffuse through the dielectric layer 102 and into fin 106 to create a silicon germanium fin 106 through high temperature annealing, as previously described herein. According to at least one embodiment, the silicon germanium cladding layer 112 shown in FIGS. 2 and 3 can be subjected to an annealing process at a temperature greater than, for example, approximately 1832° F. (1000° C.) to approximately 1922° F. (1050° C.). As the silicon germanium cladding layer 112 oxidizes, the germanium (Ge) ions are rejected (i.e., condensed) and formed over the semiconductor fins 106. Accordingly, the Ge ions are driven into the semiconductor fins 106. The annealing process can cure defects that may be present in the semiconductor fins 106. Accordingly, an improved surface for growing an epitaxial layer from the exposed upper surface and sidewalls of the fins 106 can be provided.

As shown in FIG. 4, the high concentration germanium silicon germanium or germanium can be removed from the semiconductor device 100 through a wet clean process (e.g., gaseous or liquid) such that silicon germanium fins are formed in the pFET region of the semiconductor device and silicon fins remain in the nFET region of the semiconductor device. For example, silicon germanium cladding layer can be removed using, for example a wet etching process, to expose one or more silicon germanium integrated semiconductor fins 106. That is, the silicon germanium integrated fins include diffused silicon germanium that is integrated within the fin, as opposed to being grown from an external seed layer surface of the fin. It is appreciated that a portion of the remaining block masking layer 110 can be etched when removing the silicon germanium cladding layer 112. Accordingly, a physical junction between the silicon germanium and the fin can be excluded. In at least one embodiment, the diffused portion is integrated completely within the fin.

In addition, the silicon germanium diffused fin 106 can have a high concentration of Ge ions. According to at least one exemplary embodiment, the percentage of Ge ions in the diffused fin portion 106 may be greater than or equal to 55% with respect to the percentage of silicon ions. Therefore, a silicon germanium semiconductor fin having improved and enhanced electron hole mobility may be provided. That is, the electron hole mobility through the silicon germanium fins can be increased and improved with respect to the electron hole mobility through silicon fins 106 that exclude the germanium ions. Although not illustrated, a gate stack can be formed on one or more of the silicon germanium fins according to various methods understood by those ordinarily skilled in the art. For example, a replacement metal gate (RMG) process can be performed after forming the SiGe fins.

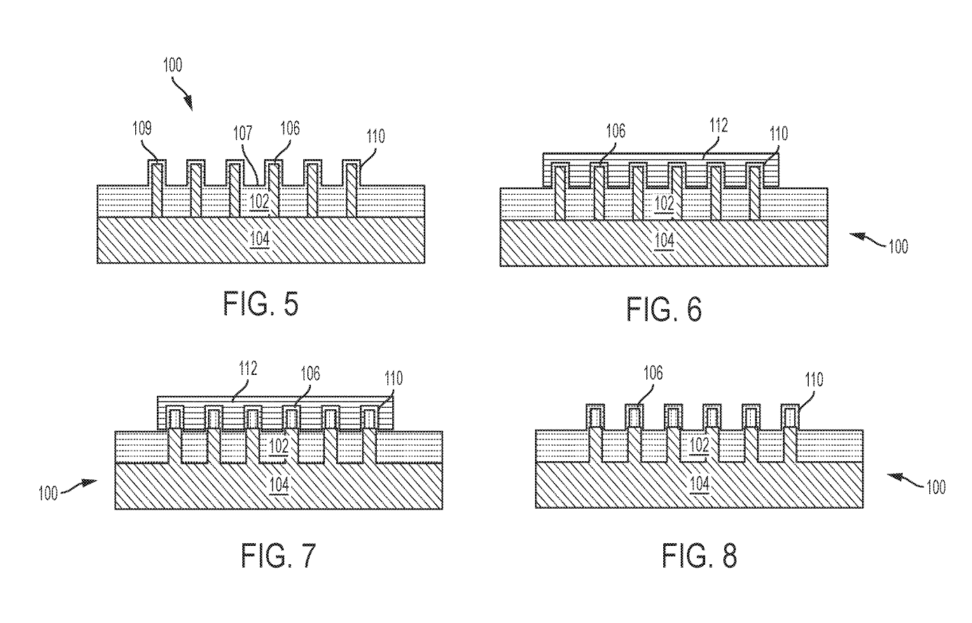

FIGS. 5 to 8 illustrate an embodiment in which tall silicon germanium fins 106 can be formed for bulk finFET devices. For example, after bulk fin patterning and single or dual shallow trench isolation, the local shallow trench isolation oxide 107 can be recessed to reveal a top portion 109 of the fins 106. A conformal oxide layer can be deposited around the fins and the nFET region can be masked, e.g., with a boron nitride (BN) mask. A sacrificial metalloid 112, e.g., silicon germanium containing greater than or equal to 55% germanium with respect to the silicon or pure germanium, can be deposited non-selectively across the semiconductor device 100.

In FIG. 7, the germanium from the cladding layer 112 can thermally diffuse through the dielectric layer 102 and into fin 106 to create a silicon germanium fin 106 through high temperature annealing, as previously described herein. According to at least one embodiment, the silicon germanium cladding layer 112 shown in FIGS. 6 and 7 can be subjected to an annealing process at a temperature greater than, for example, approximately 1832° F. (1000° C.) to approximately 1922° F. (1050° C.). As the silicon germanium cladding layer 112 oxidizes, the germanium (Ge) ions are rejected (i.e., condensed) and formed over the semiconductor fins 106. Accordingly, the Ge ions are driven into the semiconductor fins 106. The annealing process can cure defects that may be present in the semiconductor fins 106. Accordingly, an improved surface for growing an epitaxial layer from the exposed upper surface and sidewalls of the fins 106 can be provided.

As shown in FIG. 4, the high concentration germanium silicon germanium or germanium can be removed from the semiconductor device 100 through a wet clean process (e.g., gaseous or liquid) such that silicon germanium fins are formed in the pFET region of the semiconductor device and silicon fins remain in the nFET region of the semiconductor device. For example, silicon germanium cladding layer can be removed using, for example a wet etching process, to expose one or more silicon germanium integrated semiconductor fins 106. That is, the silicon germanium integrated fins include diffused silicon germanium that is integrated within the fin, as opposed to being grown from an external seed layer surface of the fin. It is appreciated that a portion of the remaining block masking layer 110 can be etched when removing the silicon germanium cladding layer 112. Accordingly, a physical junction between the silicon germanium and the fin can be excluded. In at least one embodiment, the diffused portion is integrated completely within the fin.

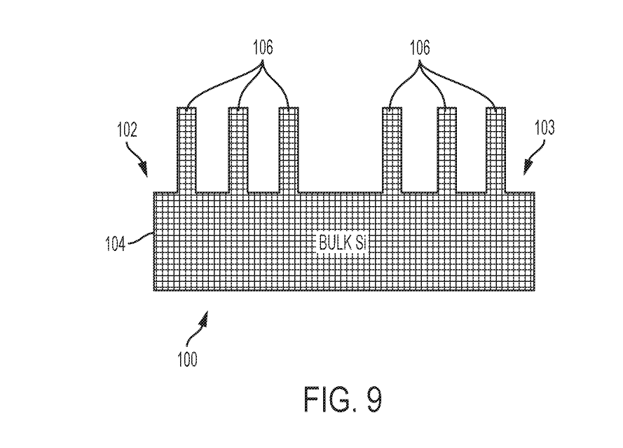

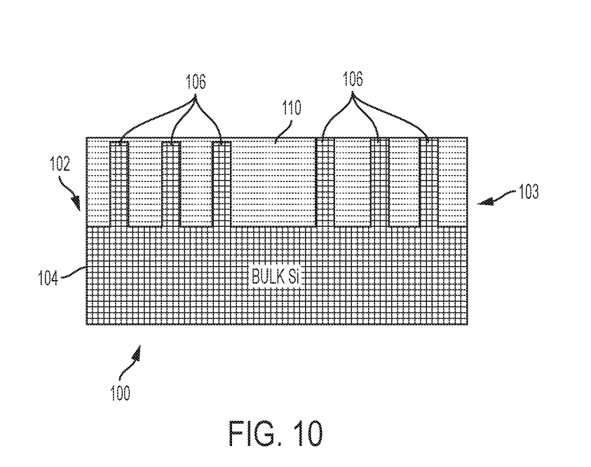

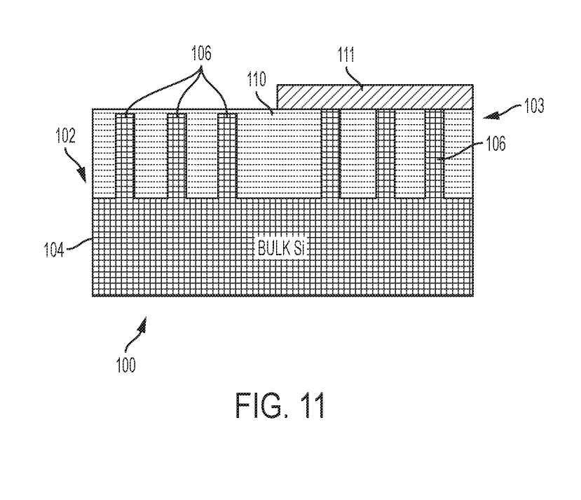

Referring to FIG. 9, for example, a semiconductor device 100 includes a first semiconductor structure (e.g., pFET) 102 and a second semiconductor structure (e.g., nFET) 103 formed on a bulk substrate (e.g., a Si substrate) 104. A block oxide layer 103 can be deposited on the semiconductor device 100 to cover the semiconductor fins 106 corresponding to the pFET 102 and the nFET 103 as illustrated in FIG. 10. The block oxide layer 110 may be formed from, for example, SiO₂.

Turning to FIG. 11, a block masking layer 111 can be formed on an upper surface of the oxide layer 110 and patterned such that the remaining block masking layer 111 covers the nFET 103, while exposing the oxide block layer 110 corresponding to the pFET. The block masking layer 111 may be formed from, for example, silicon nitride (Si₃N₄).

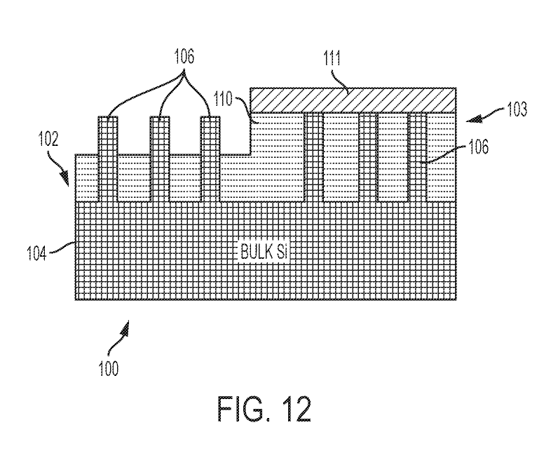

Referring now to FIG. 12, the exposed block oxide layer 110 can be etched according to an RIE process. The ME process can be selective to recess the block oxide layer 110, while leaving the fins intact. Accordingly, upper portions of silicon fins 106 corresponding to the pFET 102 can be exposed.

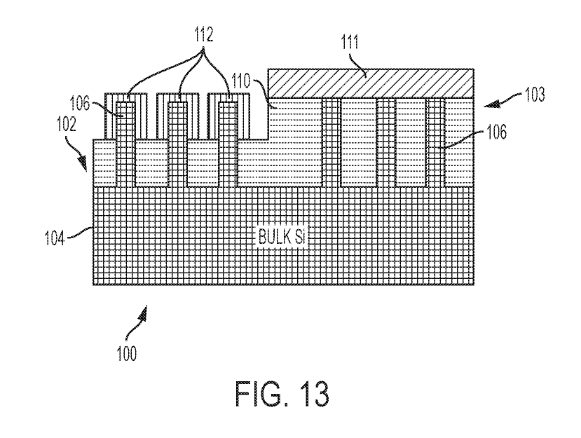

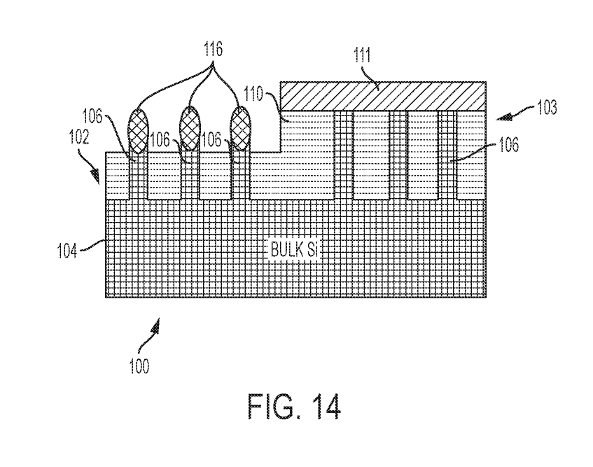

In FIG. 13, a silicon germanium cladding layer 112 may then be epitaxially grown on the exposed Si fins 106 of the pFET 102, while the block masking layer 111 prevents the cladding layer 112 from being grown on the silicon fins 106 corresponding to the nFET 103. Although not illustrated, the exposed silicon fins 106 can be annealed prior to epitaxially growing the silicon germanium cladding layer 112 as discussed in detail above. Oxidation of the silicon germanium cladding layer 112 can then be performed as discussed in detail previously herein to form silicon germanium on the pFET 102, while maintaining silicon fins 106 excluding germanium ions on the nFET 103 as illustrated in FIG. 14.

The formation of SiGe semiconductor fins as described above may be performed prior to performing a RMG process for forming a respective gate stack. According to another exemplary embodiment, however, the SiGe fins may be integrated with a RMG process flow.

It will also be understood that when an element, such as a layer, region, or substrate is referred to as being “on” or “over” another element, it can be directly on the other element or intervening elements may also be present. In contrast, when an element is referred to as being “directly on” or “directly over” another element, there are no intervening elements present, and the element is in contact with another element.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

As used herein, the articles “a” and “an” preceding an element or component are intended to be nonrestrictive regarding the number of instances (i.e. occurrences) of the element or component. Therefore, “a” or “an” should be read to include one or at least one, and the singular word form of the element or component also includes the plural unless the number is obviously meant to be singular.

As used herein, the terms “invention” or “present invention” are non-limiting terms and not intended to refer to any single aspect of the particular invention but encompass all possible aspects as described in the specification and the claims.

As used herein, the term “about” modifying the quantity of an ingredient, component, or reactant of the invention employed refers to variation in the numerical quantity that can occur, for example, through typical measuring and liquid handling procedures used for making concentrates or solutions. Furthermore, variation can occur from inadvertent error in measuring procedures, differences in the manufacture, source, or purity of the ingredients employed to make the compositions or carry out the methods, and the like. In one aspect, the term “about” means within 10% of the reported numerical value. In another aspect, the term “about” means within 5% of the reported numerical value. Yet, in another aspect, the term “about” means within 10, 9, 8, 7, 6, 5, 4, 3, 2, or 1% of the reported numerical value.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A method, comprising:
forming a semiconductor fin on a semiconductor substrate, wherein the forming the semiconductor fin further comprises:
forming a first plurality of silicon fins on the semiconductor substrate to define a pFET; and
forming a second plurality of silicon fins on the semiconductor substrate to define an nFET;
depositing a cladding layer on a portion of the semiconductor fin, wherein the cladding layer comprises a metalloid;
annealing the semiconductor substrate to oxidize the cladding layer such that ions are condensed therefrom and are diffused into the semiconductor fin while the cladding layer is converted to an oxide layer; and
removing the oxide layer to expose the semiconductor fin having a diffused fin portion comprising greater than or equal to 55% of the metalloid;
further comprising forming SiGe fins in a pFET channel of the semiconductor device, wherein a source and drain of the pFET device comprise Si fins.

2. The method of claim 1, further comprising forming a gate stack after forming the semiconductor fin comprising greater than or equal to 55% of the metalloid.

3. The method of claim 1, wherein the semiconductor fin is formed from silicon, the cladding layer is formed from germanium or silicon germanium, and the condensed ions are germanium ions that form a silicon germanium fin in response to the diffusing.

4. The method of claim 3, wherein the percentage of germanium ions in the silicon germanium fin are greater than 55 percent with respect to silicon ions.

5. The method of claim 4, wherein the oxidizing the cladding layer is performed using one of a dry thermal oxidation process or a wet thermal oxidation process.

6. (canceled)

7. The method of claim 1, further comprising masking the nFET before depositing the cladding layer to form metalloid fins comprising silicon or silicon germanium in the pFET.

8. (canceled)

9. A method, comprising:
forming a semiconductor fin on a semiconductor substrate, wherein the forming the semiconductor fin further comprises:
forming a first plurality of silicon fins on the semiconductor substrate to define a pFET; and
forming a second plurality of silicon fins on the semiconductor substrate to define an nFET;
bulk patterning the fin and forming a shallow trench isolation oxide around the fin;
recessing the shallow trench isolation oxide to reveal a top portion of the semiconductor fin;
depositing a cladding layer on a portion of the semiconductor fin, wherein the cladding layer comprises a metalloid;
annealing the semiconductor substrate to oxidize the cladding layer such that ions are condensed therefrom and are diffused into the semiconductor fin while the cladding layer is converted to an oxide layer; and
removing the oxide layer to expose the semiconductor fin having a diffused fin portion comprising greater than or equal to 55% of the metalloid;
further comprising forming SiGe fins in a pFET channel of the semiconductor device, wherein a source and drain of the pFET device comprise Si fins.

10. The method of claim 9, further comprising forming a gate stack after forming the semiconductor fin comprising greater than or equal to 55% of the metalloid.

11. The method of claim 10, wherein the semiconductor fin is formed from silicon, the cladding layer is formed from germanium or silicon germanium, and the condensed ions are germanium ions that form a silicon germanium fin in response to the diffusing.

12. The method of claim 11, wherein the percentage of germanium ions in the silicon germanium fin are greater than 55 percent with respect to silicon ions.

13. The method of claim 12, wherein the oxidizing the cladding layer is performed using one of a dry thermal oxidation process or a wet thermal oxidation process.

14. (canceled)

15. The method of claim 9, further comprising masking the nFET before depositing the cladding layer to form metalloid fins comprising silicon or silicon germanium in the pFET.

16. The method of claim 9, further comprising tuning the fin height in the pFET.

17. A semiconductor device, comprising:
a semiconductor substrate, wherein the substrate comprises a bulk substrate, a semiconductor on insulator, or a combination comprising at least one of the foregoing;
a first semiconductor fin on the semiconductor substrate in a pFET region of the semiconductor substrate, wherein the semiconductor fin comprises germanium in an amount of greater than or equal to 55%;
a second semiconductor fin on the semiconductor substrate in an nFET region of the semiconductor substrate, wherein the semiconductor fin comprises silicon;
a dielectric layer deposited around the first semiconductor fin on the semiconductor substrate in the pFET region and around the second semiconductor fin on the semiconductor substrate in nFET region;
further comprising SiGe fins in a pFET channel of the semiconductor device and Si fins in a source and drain of the pFET device.

18. The semiconductor device of claim 17, further comprising a source and drain, wherein the first semiconductor fin is disposed within the source and drain.

19. The semiconductor device of claim 17, further comprising a gate stack on an upper surface and sidewalls of the first semiconductor fin such that a semiconductor gate channel is formed beneath the gate stack.

20. The semiconductor device of claim 17, wherein the first semiconductor fin comprises silicon germanium, with germanium present in an amount of greater than or equal to 55% with respect to the silicon.
